(19) United States
(12) Patent Application Publication
(10) Pub. No.: US 2006/0091551 A1
(43) Pub. Date: May 4, 2006

(54) Differentially metal doped copper damascenes

(75) Inventors: Chun-Chieh Lin, Chu-Tung (TW); Shih-Wei Chou, Taipei (TW); Minghsing Tsai, Chu-pei City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/977,596

(22) Filed: Oct. 29, 2004

(51) Int. Cl. H01L 23/52; H01L 21/4763

(52) U.S. Cl. 257/762; 438/687; 438/638; 257/775; 438/652

(57) ABSTRACT

A method of forming a copper filled semiconductor feature having improved bulk properties including providing a semiconductor process wafer having a process surface including an opening for forming a semiconductor feature; depositing at least one metal dopant containing layer over the opening to form a thermally diffusive relationship to a subsequently deposited copper layer; depositing said copper layer to substantially fill the opening; and, thermally treating the semiconductor process wafer for a time period sufficient to distribute at least a portion of the metal dopants to collect along at least a portion of the periphery of said copper layer including a portion of said copper layer grain boundaries.

### FIELD OF THE INVENTION

This invention generally relates to methods for forming copper filled semiconductor features and more particularly to a method for producing copper filled semiconductor feature in a metallization layer to produce differentially metal (impurity) doped copper damascenes, depending on the width of the copper damascene, to improve a copper electromigration resistance including void formation while maintaining an acceptably low resistivity.

### BACKGROUND OF THE INVENTION

Sub-micron multi-level metallization is one of the key technologies for ultra large scale integration (ULSI). The multilevel interconnects that lie at the heart of this technology require formation of conductive interconnect features having a variety of widths, including dual damascenes and interconnect lines. Reliable formation of these interconnect features is critical to the functioning and reliability of the semiconductor device formed.

Copper and copper alloys have become the metal of choice for forming conductive interconnect features in integrated circuits due primarily due to its low resistivity. Copper and its alloys have lower resistivities compared to other metals such as aluminum. These characteristics are critical for achieving higher current densities with increased device speed. Copper, however, has exhibited certain processing problems that must be overcome to achieve a mature copper metal interconnect semiconductor processing technology. For example, copper is typically deposited by an electroplating process using an electroplating cell to process a single wafer. An electrolyte including various additives is present in the electroplating cell to accomplish electroplating of copper, which is a substantially conformal plating process.

Following the copper plating process to backfill openings and a CMP planarization step, the copper damascenes may be subjected to subsequent thermal processes including annealing the electrodeposited copper and depositing overlying material layers. Frequently, such subsequent thermal processes may induce copper diffusion including the formation of hillocks or protrusions on the copper surface portion, as well as forming voids or increasing the size of existing voids within the deposited copper interconnect.

Other problems associated with copper filled semiconductor features include the undesired growth of copper grain size in subsequent thermal processes or the formation of copper oxides along grain boundaries thereby degrading (increasing) an electrical resistivity. In addition, copper diffusion may take place slowly over time under the influence of one or more of electrical field gradients (electromigration), thermal gradients, and stress gradients, thereby degrading performance and reliability.

While it is known that the addition of metal dopants into the copper may serve to reduce copper diffusion, the addition of metal dopants also increases the resistivity of the copper. Prior art processes for introducing dopants into the copper filled features at dilute levels teach the introduction of the metal dopant during the electroplating step, where a predetermined amount of metal dopant is introduced into the electroplating bath.

One problem with prior art processes is that copper features having different sizes behave differently with respect to defect formation caused by copper diffusion processes. In an electroplating process of the prior art, all metal interconnects in a metallization layer are formed to have about the same level of metal doping, and thereby about the same resistance to defect formation caused by copper diffusion processes.

These and other shortcomings demonstrate a need in the integrated circuit semiconductor device processing art to develop a method for forming copper filled features in a metallization layer with metal doping levels adjusted for differently sized damascene features to improve a resistance defects associated with copper diffusion processes while maintaining an acceptable copper resistivity.

It is therefore an object of the invention to provide a method for forming copper filled features in a metallization layer with metal doping levels adjusted for differently sized damascene features to improve a resistance defects associated with copper diffusion processes while maintaining an acceptable copper resistivity, in addition to overcoming other shortcomings and deficiencies of the prior art.

### SUMMARY OF THE INVENTION

To achieve the foregoing and other objects, and in accordance with the purposes of the present invention, as embodied and broadly described herein, the present invention provides

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIG. 1A-1F are cross-sectional side views of a portion of a semiconductor a device at stages of manufacture according to embodiments of the present invention.

FIG. 2 shows exemplary ECD cells in a process flow according to an embodiment of the present invention.

FIG. 3 is a process flow diagram including several embodiments of the present invention.

### DETAILED DESCRIPTION OF THE PREFERRED EMBODIMENTS

Although the method of the present invention is explained with reference to copper interconnect (trench) lines having respectively different widths in a single metallization layer, it will be appreciated that the method may be applied to any copper filled feature including single damascene features such as bonding pads, interconnect lines, and vias as well as dual damascene features, for example an interconnect lines having a via portion underlying the interconnect line portion. For example, the method of the present invention advantageously suppresses copper diffusion in larger width damascenes wile maintaining a desired resistivity in narrower width damascenes by advantageously forming copper portions having different metal doping concentrations in different damascene width sizes in a single metallization layer in a multi-step electro-chemical deposition (ECD) process. According to an aspect of the invention, copper damascene structures having different widths in a metallization layer may be selectively formed with a desired dopant level to increase reliability and performance of copper damascenes.

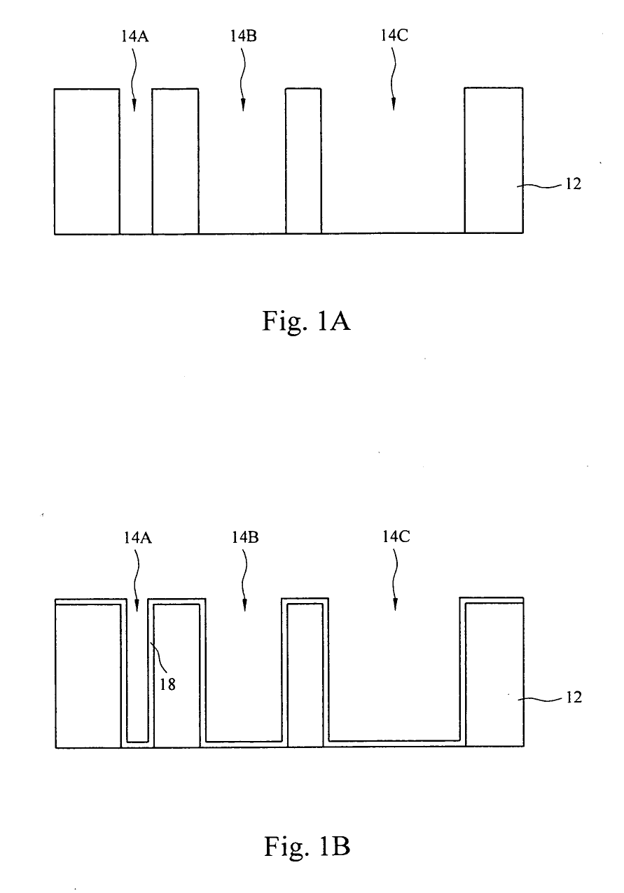

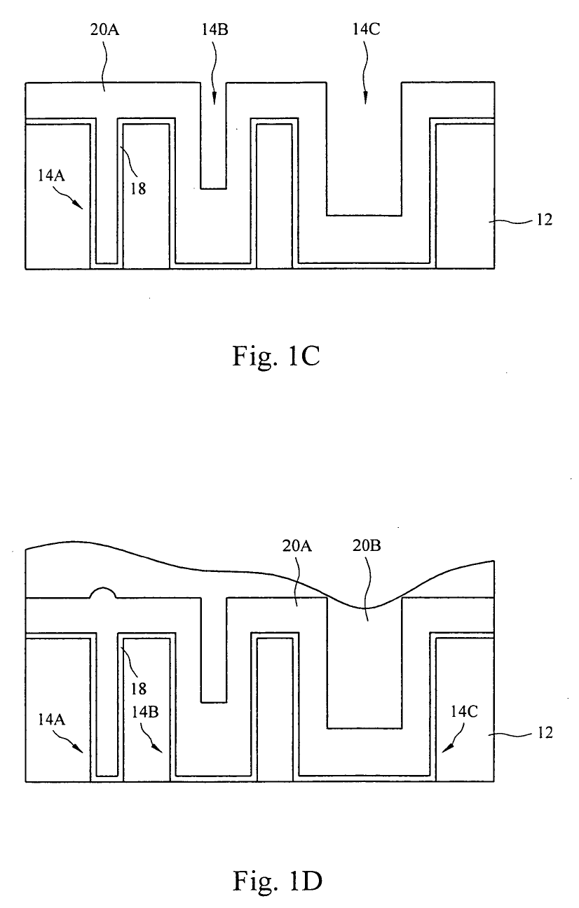

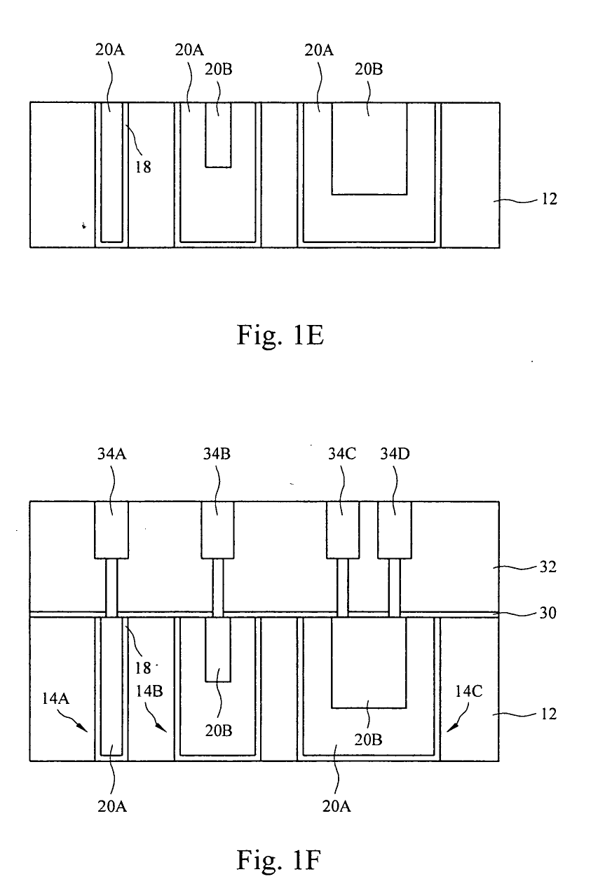

Referring to FIG. 1A is shown a partial view of a metallization layer in a multi-layer semiconductor device. Shown are three openings e.g., 14A, 14B, and 14C having different respective widths, e.g., W1, W2, and W3. The openings are formed by conventional lithographic patterning and etching processes in dielectric insulating layer 12, which may be any organic or inorganic dielectric insulating layer including a silicon oxide based dielectric, preferably including low-k dielectrics such as carbon doped silicon oxide, organo-silicate glass (OSG) and fluorinated silicate glass (FSG). It will be appreciated that the openings may communicate with underlying conductive portions (not shown) including vias (e.g., a dual damascene) or interconnect lines. It will also be appreciated that a dielectric anti-reflectance coating (DARC) layer (not shown), e.g., SiON may be formed overlying the dielectric insulating layer 12 prior to the lithographic patterning and etching process.

Still referring to FIG. 1A, the three exemplary openings shown include openings having a maximum width of less than about 1 micron, for example interconnect line (trench) opening 14A. Trench opening 14B has a width of about 1 micron to about 10 microns and trench opening 14C has a width of greater than about 10 microns.

Referring to FIG. 1B a barrier layer 18 is preferably formed to line the openings prior to ECD processes to prevent copper diffusion into the dielectric insulating layer 12, also referred to as an inter-metal dielectric (IMD) layer. The barrier layer 18 may be formed of one or more layers of a refractory metal and refractory metal nitride, preferably formed of a TaN layer. The barrier layer 18 may additionally be formed of one or more of tantalum (Ta), tantalum nitride (TaN), titanium (Ti), titanium nitride (TiN) or silicided titanium nitride (TiSiN). The barrier layer is formed by PVD and or CVD methods, including silicidation and nitridation processes known in the art. Preferably, the barrier layer 18 is formed having a thickness of about 50 Angstroms to about 300 Angstroms.

Referring to FIG. 1C, in an important aspect of the invention a first conventional ECD process is carried out following deposition of a continuous metal (e.g., copper) seed layer over the process surface by a PVD or CVD process. The first ECD process is carried out to deposit copper and preferably a metal dopant at a first concentration or concentration range (e.g., including an increasing upward direction concentration gradient) to fill the narrowest openings e.g., 14A having a width of less than about 1 micron, while leaving larger width openings e.g., 14B and 14C partially filled e.g., a first metal dopant portion e.g., 20A. The level of the copper filling following the first ECD process in the larger width openings will depend on the width of the openings (e.g., all openings formed at an equal depth) and is shown in an exemplary implementation. It will be appreciated that ECD of copper and metal dopant results in substantially conformal deposition of metal doped copper.

The ECD process may be carried out in any type of electrodeposition apparatus, but is preferably an ECD cell for processing a single wafer. In addition, any type of waveform may be used to deposit the copper and metal salt, including a continuous or pulsed wave form, including applying a forward pulsed (anodic) waveform according to a desired Voltage potential to deposit both copper and one or more selected metal dopants. It will be appreciated that the relative amount of copper and metal dopant deposited will depend primarily on the copper ion (e.g., copper salt or Cu anode) and metal dopant ion (e.g., metal dopant salt) concentration, but may be also determined in part by the respective reduction potentials of the metal dopant and copper and the Voltage potential applied during ECD. Preferably, a desired amount of metal dopant to achieve a desired metal dopant concentration in a plated copper portion is added to the electrolyte, e.g., prior to or during the ECD process. The metal dopant is preferably deposited at about a constant concentration but may be deposited to form a doping gradient within a range of metal dopant concentrations, preferably increasing in an increasing thickness direction.

It will also be appreciated that the desired amount of metal dopant will depend on a balance of resistivity requirements and a desired resistance to copper diffusion, e.g., electro or stress induced migration (diffusion). For example, at least the first ECD process filling the narrower width openings retains a copper electrical resistivity within about 10% percent of a substantially pure copper layer. In one embodiment, the first ECD process preferably produces a first metal dopant concentration zone (portion) e.g., 20A in the filled and partially filled openings at a lower metal dopant concentration compared to subsequent ECD processes which fill remaining unfilled portions of the larger width openings as shown below. For example the metal dopant concentration may range from a dopant concentration e.g., 0 atomic wt % to about 5 atomic wt %. Any metal dopant capable of being solvated as a metal ion in an electrolyte solution and undergoing a reduction reaction to form metal doped plated copper may be used. Preferred metal dopants include one or more of Sn, Wn, Zn, Zr, Ti, Mg, Al, Ag, Au, Co, P, Pd, and In. The preferred metal dopants have been found to advantageously produce superior resistance to electro and stress induced diffusion of copper.

Referring to FIG. 1D, at least a second ECD process is then carried out to deposit a second metal doped copper portion e.g., 20B (e.g., substantially conformal deposition) to fill the remaining unfilled portions of the wider width openings, e.g., 14B and 14C. Preferably, the second ECD process is carried out in a separate ECD cell, as it has been found that the metal dopant (e.g., metal dopant salt) concentration is better controlled over a larger range in this way rather than adjusting the metal dopant salt concentration in a single ECD apparatus according to different processing steps. Preferably, the second (or subsequent) ECD processes produce metal dopant concentration zones having a higher metal dopant concentration or concentration range compared to previous (e.g., first) ECD processes, such that the metal dopant concentration zones e.g., 20A and 20B, e.g., rectangular in shape due to the substantially conformal nature of the ECD, produce layers (zones) of progressively increasing metal dopant concentrations e.g., in a direction both upward and toward the center portion of the opening.

It will be appreciated that the second or subsequent ECD processes may include the same or different dopants as the first ECD process. It will be appreciated that more than two metal dopant concentration zones may be produced in progressively wider openings by carrying out more than two successive ECD processes, preferably each having different (e.g., increasing) metal dopant electrolyte concentration and preferably carried out in different ECD cells.

Referring to FIG. 1E, following the final ECD process to fill the widest openings e.g., 14C, a conventional copper CMP process is carried out to remove excess copper including removing barrier layer and DARC layer portions overlying the IMD layer to complete the copper damascene formation process. Subsequent annealing processes in an inert atmosphere may optionally be carried out e.g., from about 200° C. to about 300° C., to thermally activate diffusion of the metal dopants, e.g. to deposit along grain boundaries.

Referring to FIG. 1F, an overlying metallization layer may then be formed by similar processes by first forming a capping or etch stop layer 30 followed by forming an overlying IMD layer 32 similar to IMD layer 12 and forming overlying damascene interconnects such as e.g., dual damascenes 34A, 34C and 34D, as well as single damascenes e.g., 34B. The damascenes interconnects may be formed by a multi-step ECD process including metal doped copper portions as previously outlined (barrier layer no shown for clarity) or may formed by a single step ECD process including doped or undoped copper as well as a gradient of metal doping increasing in an upward direction.

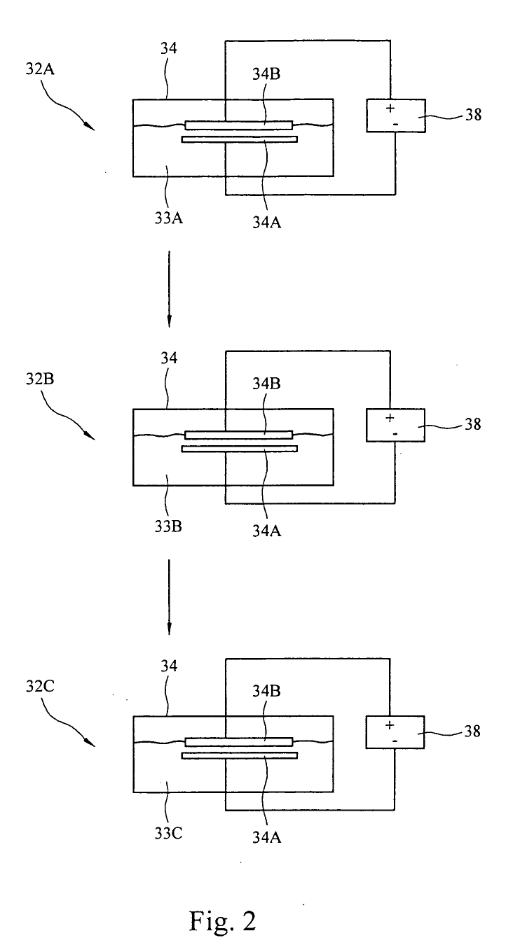

Referring to FIG. 2 is a schematic diagram depicting a process flow using separate exemplary ECD cells for carrying out a multi-step ECD process. A first ECD cell 32A is provided for ECD of copper over a single process wafer. The cell includes an electrolyte holding chamber 34 for holding electrolyte e.g., 33A within the chamber, an anode plate 36A in communication with an electrical power source 38 for producing ECD waveforms and a process wafer 36B (cathode) in communication with an electrical power source 38, the cathode an anode together producing an electrical potential through electrolyte disposed between the anode and process wafer. For example, the first ECD cell 32A includes an electrolyte 33A including a copper ion source (e.g., copper salt and/or copper anode) and a first metal dopant (e.g., metal salt) concentration. A process wafer having multiple damascene opening widths is loaded into the first ECD cell and a first ECD process carried out to fill opening widths with a first metal doped copper portion having a first width range while leaving larger width openings partially filled.

The process wafer 36B is then transferred to ECD cell 32B also including an electrolyte 33B including a copper ion source (e.g., copper salt and/or copper anode) and a second metal dopant ion source (e.g., metal salt) concentration, preferably a greater concentration compared to the first metal dopant concentration. A second ECD process is then carried out in ECD cell 32B to fill a second range of width openings larger than the first width range with a second metal doped copper portion while leaving larger width openings partially filled. A third ECD cell 32C may be provided similar to first and second ECD cells, e.g., 32A and 32B, but including an electrolyte 33C with yet a higher concentration of metal dopant to carry out a third copper ECD process to fill a remaining portion of the openings left unfilled by the first and second ECD processes with a third metal doped copper portion.

Thus, a method has been presented whereby damascene openings having different widths in a metallization layer (IMD layer) may be subjected to two or more ECD process to form different zone of a metal dopant concentration, e.g., having a progressively increasing metal dopant concentration and a progressively increasing number of zones with respect to an increasing width of the openings. In this manner, small width openings including narrow interconnect lines (including vias) may be formed with a lower metal doping concentration to increase a resistance to both electro and stress induced copper diffusion while maintaining a low copper electrical resistivity. On the other hand, wider copper damascenes which have been found to exhibit a greater sensitivity to defect formation due to stress induced copper diffusion, may be formed with an increased metal dopant concentration in an upper portion of the damascene thereby increasing a resistance to stress-induced migration without affecting the previously filled narrower damascenes. By using separate ECD cells in a multi-step ECD process, a desired metal doping concentration may be more easily controlled and reproduced over a larger range as well as improve an in-line process flow. The method is particularly effective in reducing defects (e.g., void growth) induced in wider copper interconnects underlying narrower interconnects including vias.

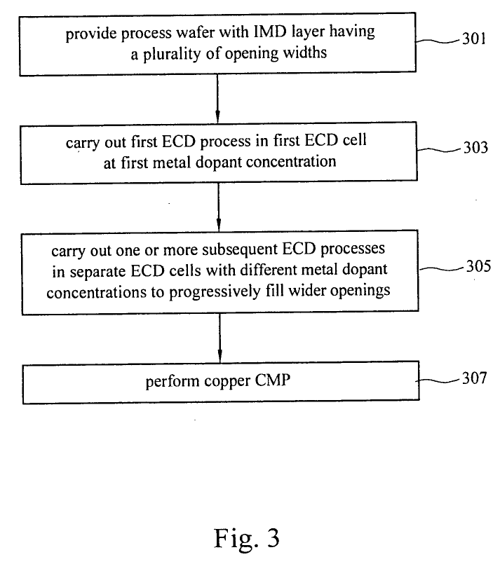

Referring to FIG. 3 is a process flow diagram including several embodiments of the present invention. In process 301, an IMD layer is provided with a plurality of damascene opening width ranges including relatively narrow and relatively wide openings. In process 303, a first copper ECD process in a first ECD cell including a first metal dopant concentration is carried out to deposit a first metal doped copper portion including filling relatively narrower openings. In process 305, one or more subsequent ECD processes are carried out in different ECD cells with different metal dopant concentrations (e.g., increased concentration) to progressively fill wider openings. In process 307, a CMP process is carried out to complete formation of the copper damascene features.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method of forming metal doped copper damascenes according to an electro-chemical deposition (ECD) process comprising the steps of:
providing a semiconductor process wafer having a process surface comprising a dielectric insulating layer and a plurality of openings formed therein;
carrying out a first copper ECD process to deposit a first metal doped copper portion having a first metal dopant concentration to fill a first portion of the openings comprising a first range of opening widths while leaving unfilled openings comprising at least a second range of opening widths wider than the first range; and,
carrying out at least a second copper ECD process to deposit a second metal doped copper portion having a second metal dopant concentration to fill remaining portions of the unfilled openings.

2. The method of claim 1, wherein the first ECD process and the at least a second ECD process are carried out in separate respective ECD cells having different respective metal dopant concentrations comprising an electrolyte.

3. The method of claim 1, wherein the second metal doped copper portion has a relatively higher metal dopant concentration than the first metal doped copper portion.

4. The method of claim 1, wherein the first and at least a second range of opening widths are selected from the group consisting of less than about 1 micron, about 1 to about 10 microns, and greater than about 10 microns.

5. The method of claim 1, wherein the metal dopants are selected from the group consisting of Sn, Wn, Zn, Zr, Ti, Mg, Al, Ag, Au, Co, P, Pd, and In.

6. The method of claim 1, wherein the at least a second ECD process comprises a different metal dopant compared to the first ECD process.

7. The method of claim 1, wherein the first and at least a second ECD processes comprise a waveform selected from the group consisting of pulsed and continuous.

8. The method of claim 1, wherein the plurality of openings comprise a barrier layer comprising a material selected from the group consisting of Ta, TaN, Ti, TiN, and TiSiN.

9. The method of claim 1, wherein a conductive seed layer is formed over the barrier layer prior to the first ECD process.

10. The method of claim 1, wherein the first and the at least a second metal doped copper portions have a metal dopant concentration of from about 0 atomic weight % to about 5 atomic weight %.

11. The method of claim 1, further comprising a copper chemical mechanical polish (CMP) process following filling the plurality of openings to form differentially doped copper damascenes.

12. The method of claim 11, further comprising an annealing step in an inert atmosphere to induce metal dopant diffusion following the CMP process.

13. A method of forming metal doped copper damascenes according to an electro-chemical deposition (ECD) process comprising the steps of:
providing a semiconductor process wafer having a process surface comprising a dielectric insulating layer and a plurality of openings and respective opening widths formed therein;
carrying out a first copper ECD process comprising a first metal dopant electrolyte concentration to deposit a first metal doped copper portion having a first metal dopant concentration to fill a first range of the opening widths; and,
carrying out at least a second copper ECD process comprising a second metal dopant electrolyte concentration to deposit a second metal doped copper portion having a second metal dopant concentration to fill at least a second range of the opening widths greater than the first range.

14. The method of claim 13, wherein the first ECD process and the at least a second ECD process are carried out in separate respective ECD cells having different respective metal dopant electrolyte concentrations.

15. The method of claim 13, wherein the at least a second ECD process forms the at least a second metal doped copper portion having a relatively higher metal dopant concentration than the first metal doped copper portion.

16. The method of claim 13, wherein the first and the at least a second range of the opening widths are selected from the group consisting of less than about 1 micron, about 1 to about 10 microns, and greater than about 10 microns.

17. The method of claim 13, wherein the metal dopants are selected from the group consisting of Sn, Wn, Zn, Zr, Ti, Mg, Al, Ag, Au, Co, P, Pd, and In.

18. The method of claim 13, wherein the at least a second ECD process comprises a different metal dopant compared to the first ECD process.

19. The method of claim 1, wherein the first and the at least a second ECD processes comprises a waveform selected from the group consisting of pulsed and continuous.

20. The method of claim 1, further comprising a copper chemical mechanical polish (CMP) process following filling the plurality of openings to form differentially doped copper damascenes.

21. A plurality of electrochemically deposited (ECD) metal doped copper damascenes comprising:
a semiconductor process wafer comprising a dielectric insulating layer and a plurality of ECD metal doped copper damascenes comprising a plurality of widths extending through a thickness thereof;
wherein a first metal doped copper portion comprises a first metal dopant concentration to completely fill openings comprising a first range of the widths and partially fills damascenes comprising at least a second range of the widths wider than the first range; and,
wherein at least a second metal doped copper portion comprises a second metal dopant concentration filling remaining portions of the partially filled damascenes.

22. The plurality of ECD metal doped copper damascenes of claim 21, wherein the at least a second metal doped copper portion has a relatively higher metal dopant concentration than the first metal doped copper portion.

23. The plurality of ECD metal doped copper damascenes of claim 21, wherein the first and the at least a second range of the widths are selected from the group consisting of less than about 1 micron, about 1 to about 10 microns, and greater than about 10 microns.

24. The plurality of ECD metal doped copper damascenes of claim 21, wherein the metal dopants are selected from the group consisting of Sn, Wn, Zn, Zr, Ti, Mg, Al, Ag, Au, Co, P, Pd, and In.

25. The plurality of ECD metal doped copper damascenes of claim 21, wherein the at least a second metal doped copper portion comprises a different metal dopant compared to the first metal doped copper portion.

26. The plurality of ECD metal doped copper damascenes of claim 21, wherein the plurality of damascenes comprise a barrier layer comprising a material selected from the group consisting of Ta, TaN, Ti, TiN, and TiSiN.

27. The plurality of ECD metal doped copper damascenes of claim 21, wherein the first and the at least a second metal doped copper portions have a metal dopant concentration of from about 0 atomic weight % to about 5 atomic weight %.

28. A plurality of electrochemically deposited (ECD) differentially doped copper damascenes comprising:
a semiconductor process wafer comprising a dielectric insulating layer including a plurality of damascenes having a plurality of respective widths;
wherein a first metal doped copper portion having a first metal dopant concentration completely fills damascenes having a first range of the widths and partially fills damascenes having at least a second range of the widths; and,
wherein at least a second metal doped copper portion having a second metal dopant concentration fills a remaining portion of the damascenes having the at least a second range of the widths greater than the first range.

29. The plurality of ECD differentially doped copper damascenes of claim 28, wherein the at least a second metal doped copper portion has a relatively higher metal dopant concentration than the first metal doped copper portion.

30. The plurality of ECD differentially doped copper damascenes of claim 28, wherein the first and the at least a second range of widths are selected from the group consisting of less than about 1 micron, about 1 to about 10 microns, and greater than about 10 microns.
